(19) United States
(12) Patent Application Publication
(10) Pub. No.: US 2011/0248402 A1
(43) Pub. Date: Oct. 13, 2011

(54) SEMICONDUCTOR DEVICE AND METHOD FOR MANUFACTURING THE SAME

(75) Inventor: Ho Seung Choi, Bucheon (KR)

(73) Assignee: Hynix Semiconductor Inc., Icheon (KR)

(21) Appl. No.: 12/843,501

(22) Filed: Jul. 26, 2010

(30) Foreign Application Priority Data
Apr. 7, 2010 (KR) 10-2010-0031805

(51) Int. Cl. H01L 23/48; H01L 21/768

(52) U.S. Cl. 257/751; 438/643; 257/774; 257/E21.584; 257/E23.011

(57) ABSTRACT

Provided are a semiconductor device and a method for manufacturing the same. Since a plug is formed in a portion of a metal interconnection between a first metal contact and a second metal contact, an amount of a metal interconnection coupled to a second metal contact increases. Also, since the first metal contact is formed so that the upper width is narrower than the lower width by using insulation layers having a different etching selectivity when the first metal contact is formed, it is possible to substantially prevent copper ions of the meal interconnection from being migrated or separated according to the flow of a VPP electric field. Consequently, a contact-not-open phenomenon between the first metal contact and the second metal contact may be prevented.

### CROSS-REFERENCE TO RELATED APPLICATION

The present application claims priority to Korean patent application number 10-2010-0031805, filed on Apr. 7, 2010, which is incorporated by reference in its entirety.

### BACKGROUND OF THE INVENTION

The present invention relates to a semiconductor device and a method for manufacturing the same.

Generally, in a semiconductor device, a metal interconnection is formed in order to electrically couple elements or interconnections to each other and a contact plug is formed in order to couple an upper metal interconnection to a lower metal interconnection.

The metal interconnection is usually formed of aluminum (Al) and tungsten (W) which has an excellent electrical conductivity. Recent studies have been conducted to use copper as a next generation metal interconnection material. Specifically, copper can solve an RC signal delay problem in a high-integration high-speed device because copper has a far superior electrical conductivity to that of aluminum and tungsten.

However, in the case of copper, it is difficult to perform a dry etching process for forming an interconnection. Thus a Damascene process is used to form a metal interconnection of copper. A Damascene metal interconnection process is a technology which forms a metal interconnection by forming a Damascene pattern by etching an interlayer dielectric layer, and forming a metal interconnection by filling the Damascene pattern with a copper layer. The Damascene metal interconnection process may be classified into a single-Damascene process and a dual-Damascene process.

In the Damascene process an upper metal interconnection and a contact plug for contacting the upper metal interconnection and a lower metal interconnection in a multilayer metal interconnection can be formed at the same time, and a subsequent process is easily performed because height difference caused by the metal interconnections can be removed.

Furthermore, in a case where a copper layer is applied as the metal interconnection material, components of the copper layer are diffused into the substrate through the interlayer dielectric layer, as opposed to a case where an aluminum layer is applied. Since the diffused components of the copper layer act as deep level impurities within the semiconductor substrate formed of silicon, a leakage current is generated. Therefore, a diffusion barrier layer must be formed in a contact interface between the metal interconnection layer formed of copper and the interlayer dielectric layer.

### BRIEF SUMMARY OF THE INVENTION

In an embodiment of the present invention, a method for manufacturing a semiconductor device includes: forming a first insulation layer on a semiconductor substrate including a first contact; etching the first insulation layer by using a metal interconnection mask, and forming a metal interconnection by depositing a first conductive material; forming a second insulation layer on a resulting structure including the metal interconnection; forming a contact region by etching the second insulation layer by using a plug mask until the metal interconnection is exposed; forming a plug in the contact region; forming a third insulation layer on a resulting structure including the plug; forming a contact hole by etching the third insulation layer by using a second contact mask until the plug is exposed; and forming a second contact by depositing a second conductive material in the contact hole.

An upper width of the first contact is narrower than a lower width of the first contact.

The method may further include forming an etching stopper layer between the semiconductor substrate and the first insulation layer.

The first conductive material may include a barrier metal and copper (Cu).

The second conductive material may include a barrier metal and tungsten (W).

The forming of the first contact may include: forming a plurality of interlayer dielectric layers having a different etching selectivity on the semiconductor substrate; forming a first contact hole by etching the interlayer dielectric layers by using a first contact mask until the semiconductor substrate is exposed; and depositing a conductive material within the first contact hole, and etching the conductive material until the interlayer dielectric layer is exposed.

An upper interlayer dielectric layer among the plurality of the interlayer dielectric layers may have an etching rate lower than a lower interlayer dielectric layer among the plurality of the interlayer dielectric layers under the same etching condition.

The method may further include forming a diffusion barrier layer between the metal interconnection and the second insulation layer.

The diffusion barrier layer may include nitride.

The height of the plug may be approximately 5% to approximately 15% of the height of the metal interconnection.

The method may further include: depositing a barrier metal on a resulting structure including the contact region between the forming of the contact region and the forming of the plug; and etching the barrier metal to expose the metal interconnection.

In another embodiment of the present invention, a semiconductor device includes: a semiconductor substrate including a first contact; a metal interconnection coupled to the first contact; a plug disposed on the metal interconnection; and a second contact coupled to the plug.

An upper width of the first contact may be narrower than a lower width of the first contact.

The metal interconnection may include a barrier metal and copper (Cu).

The first and second contacts may include a barrier metal and tungsten (W).

The height of the plug may be approximately 5% to approximately 15% of the height of the metal interconnection.

### BRIEF DESCRIPTION OF THE DRAWINGS

FIGS. 1A to 1G are cross-sectional views illustrating a semiconductor device and a method for manufacturing the same according to an embodiment of the present invention.

### DESCRIPTION OF EMBODIMENTS

Description will now be made in detail with reference to the embodiments of the present invention and accompanying drawings. Wherever possible, the same reference numbers will be used throughout the drawings to refer to the same or like elements.

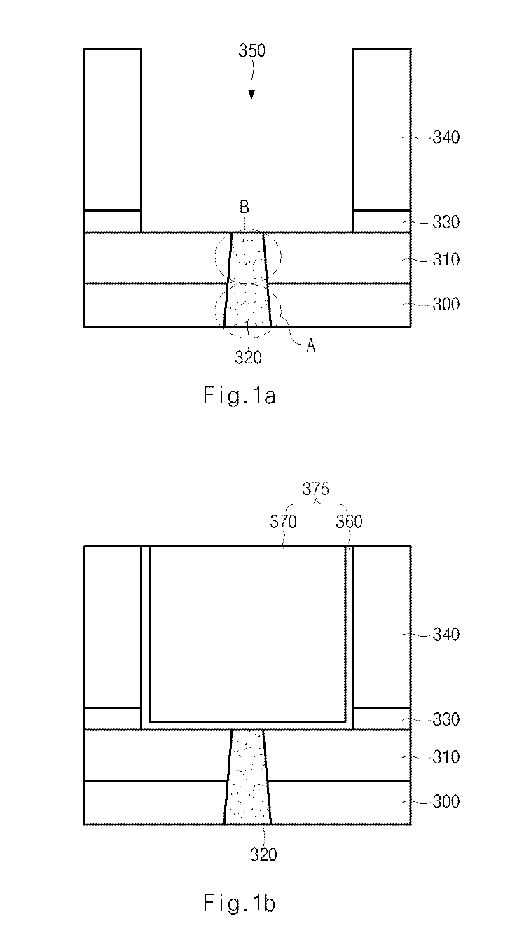

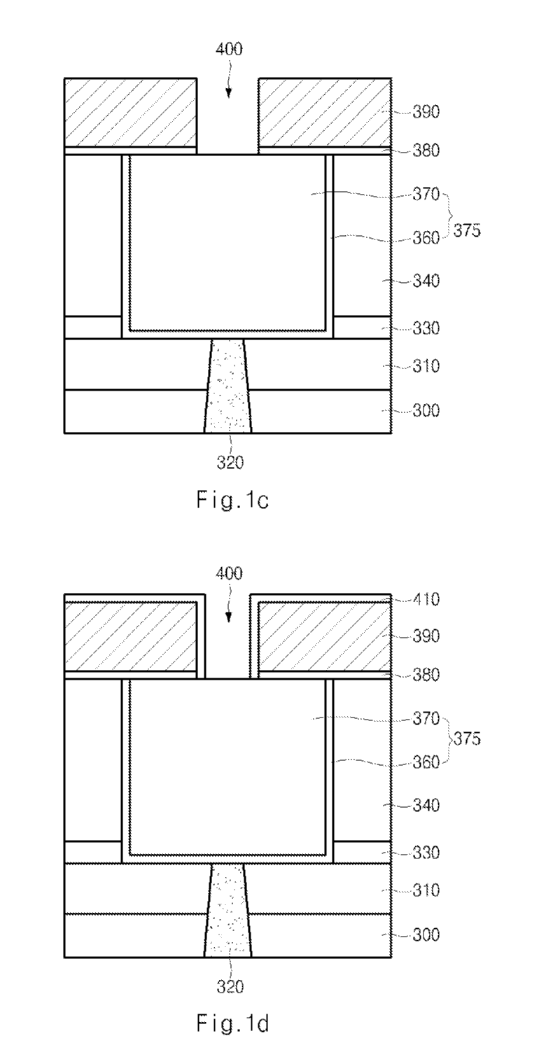

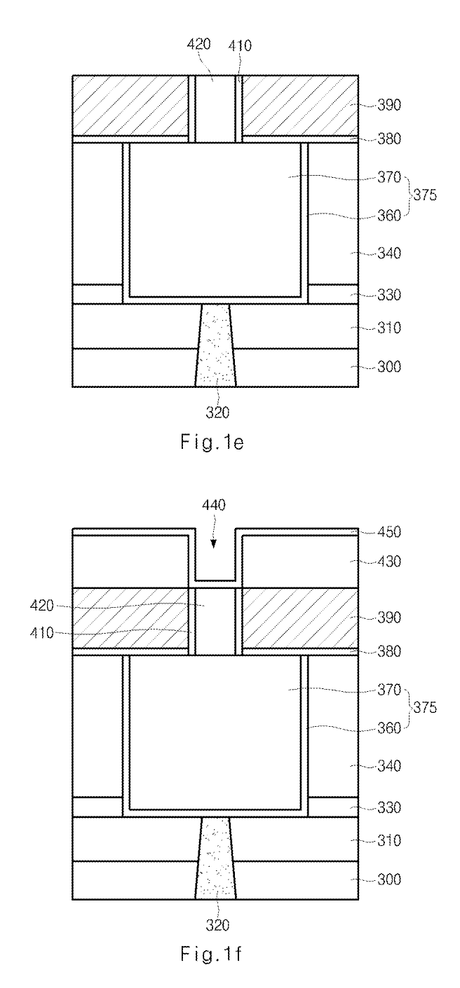

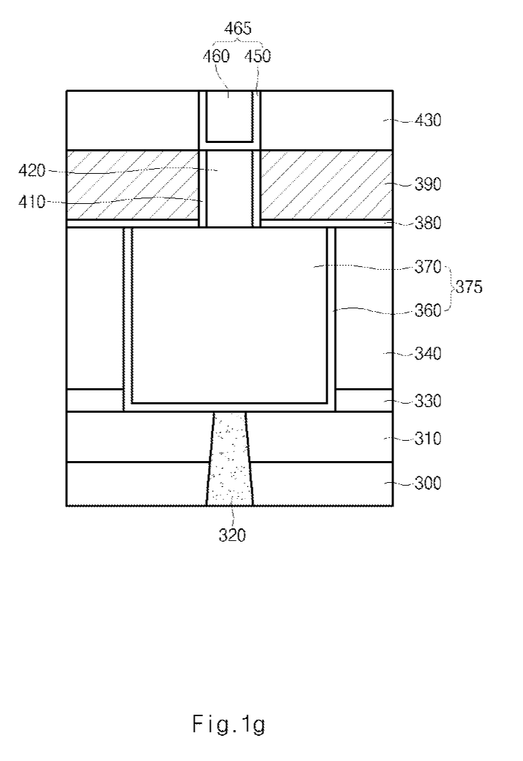

FIGS. 1A to 1G are cross-sectional views illustrating a semiconductor device and a method for manufacturing the same according to an embodiment of the present invention.

Referring to FIG. 1A, first and second interlayer dielectric layers 300 and 310 are formed on a semiconductor substrate (not shown).

A photoresist layer (not shown) is formed on a resulting structure including the second interlayer dielectric layer 310, and a photoresist pattern (not shown) is formed by an exposure process and development process using a first contact mask.

A first contact hole (not shown) is formed by etching the second interlayer dielectric layer 310 and the first interlayer dielectric layer 300 by using the photoresist pattern as an etching mask until the semiconductor substrate is exposed. A first metal contact (or first metal contact plug) 320 is then formed by depositing a first conductive material.

Due to a different etching rate between the second interlayer dielectric layer 310 and the first interlayer dielectric layer 300, the etching rate of the second interlayer dielectric layer 310 is lower than the etching rate of the first interlayer dielectric layer 300 under the conditions of the same etching time and the same etching solution. That is, the first interlayer dielectric layer 300 is etched more than the second interlayer dielectric layer 310. Therefore, since an upper width B of the first metal contact plug 320 is narrower than a lower width A the first metal contact plug 320, it is possible to substantially reduce copper ions from being migrated through the first metal contact plug 320.

An etching stopper layer 330 and a first insulation layer 340 are sequentially deposited over the second interlayer dielectric layer 310 including the first metal contact plug 320. At this time, the etching stopper layer 330 serves to prevent overetching by using an etch selectivity difference with the insulation layer when a metal interconnection region is formed. The etching stopper layer 330 may be formed of nitride. After the etching stopper layer 330 and the first insulation layer 340 are sequentially deposited, a metal interconnection region 350 is formed by etching the first insulation layer 340 and the etching stopper layer 330 until the second interlayer dielectric layer 310 is exposed.

Referring to FIG. 1B, a barrier metal 360 and a copper layer 370 are sequentially deposited in the metal interconnection region 350, and a metal interconnection 375 is formed by performing a chemical mechanical polishing (CMP) process on the copper layer 370 and the barrier metal 360 until the first insulation layer 340 is exposed. The barrier metal 360 may be formed in a Ti/TiN stack structure.

Referring to FIG. 1C, a diffusion barrier layer 380 and a second insulation layer 390 are formed on a resulting structure including the metal interconnection 375. The diffusion barrier layer 380 may be formed of nitride. The diffusion barrier layer 380 prevents diffusion of copper ions from the metal interconnection 375.

A photoresist layer (not shown) is formed on a resulting structure including the second insulation layer 390, and a photoresist pattern (not shown) is formed by an exposure process and development process using a plug mask. A contact region 400 is formed by etching the second insulation layer 390 and the diffusion barrier layer 380 by using the photoresist pattern as an etching mask until the metal interconnection 375 is exposed.

Referring to FIGS. 1D and 1E, a barrier metal 410 is deposited on a resulting structure including the contact region 400. The barrier metal 410 may be formed in a Ti/TiN stack structure. The barrier metal 410 is etched to expose the metal interconnection 375 of the contact region 400, and a plug 420 is formed by depositing a copper layer on the metal interconnection 375 exposed within the contact region 400. The height of the plug 420 may be approximately 5% to approximately 15% of the height of the metal interconnection 375. By adjusting the height of the plug 420, a buffer operation can be achieved to substantially prevent copper ions of the metal interconnection 375 from migrating or diffusing according to a Vpp (Voltage at peak power) electric field, and the resistance between the metal interconnection 375 and the first metal contact plug 320 may be adjusted.

A CMP process is performed on the plug 420 and the barrier metal 410 until the second insulation layer 390 is exposed.

Referring to FIGS. 1F and 1G, a third insulation layer 430 is formed on a resulting structure including the plug 420. A second contact hole 440 is formed by etching the third insulation layer 430 by using a second contact hole mask as an etching mask until the plug 420 is exposed.

A barrier metal 450 and a tungsten layer 460 are sequentially deposited on a resulting structure including the second contact hole 440, and a second contact (a second contact plug) 465 is formed by planarizing the tungsten layer 460 and the barrier metal 450 until the third insulation layer 430 is exposed. The barrier metal 450 may be formed in a Ti/TiN stack structure.

If a stress is generated due to a VPP electric field passing through the second metal contact 465 and the first metal contact 320, copper ions of the metal interconnection 375 may be migrated or separated to the first metal contact 320. However, in this embodiment, the migration of the copper ions through the first metal contact 320 can be more effectively prevented because the upper width of the first metal contact 320 is narrower than the lower width of the first metal contact 320. Due to the plug 420 formed on the metal interconnection 375 between the first metal contact 320 and the second metal contact 465, the migration of the copper ions of the metal interconnection 375 may be reduced.

As described above, since the plug is formed in a portion of the metal interconnection between the first metal contact and the second metal contact, an amount of the metal interconnection coupled to the second metal contact increases. Also, since the first metal contact is formed so that the upper width is narrower than the lower width by using two or more insulation layers having different etching selectivity from one another when the first metal contact is formed, it is possible to substantially prevent copper ions of the metal interconnection from being migrated or separated along the flow path of the VPP electric field. Consequently, a contact-not-open phenomenon between the first metal contact and the second metal contact may be prevented.

The above embodiments of the present invention are illustrative and not limitative. Various alternatives and equivalents are possible. The invention is not limited by the type of deposition, etching, polishing, and patterning steps described herein. Nor is the invention limited to any specific type of semiconductor device. For example, the present invention may be implemented in a dynamic random access memory (DRAM) device or nonvolatile memory device. Other additions, subtractions, or modifications are obvious in view of the present disclosure and are intended to fall within the scope of the appended claims.

What is claimed is:

1. A method for manufacturing a semiconductor device, comprising:
forming a first insulation layer over a semiconductor substrate including a first contact plug;
etching the first insulation layer to form a first insulation pattern defining a space;
forming a metal interconnect pattern within the spaced defined by the first insulation pattern;
forming a second insulation layer over the metal interconnect and the first insulating pattern;
forming a second insulation pattern by etching the second insulation layer, the second insulation pattern defining a first hole;
forming a plug within the first hole defined by the second insulation pattern, the plug being electrically coupled to the metal interconnect pattern;
forming a third insulation layer over the plug and the second insulation pattern;
forming a third insulation pattern by etching the third insulation layer, the third insulation pattern defining a second hole; and
forming a second contact plug within the second hole of the third insulation pattern, the second contact plug being electrically coupled to the plug.

2. The method according to claim 1, wherein an upper width of the first contact plug is narrower than a lower width of the first contact plug.

3. The method according to claim 1, further comprising forming an etching stop layer between the semiconductor substrate and the first insulation pattern.

4. The method according to claim 1, wherein the metal interconnect pattern comprises a barrier metal and copper (Cu).

5. The method according to claim 1, wherein the second contact plug comprises a barrier metal and tungsten (W).

6. The method according to claim 1, further comprising:
stacking a plurality of interlayer dielectric layers having different etching selectivity over the semiconductor substrate;
forming a interlayer dielectric pattern by etching the stack of the plurality of interlayer dielectric layers; and
forming the first contact plug between the interlayer dielectric patterns so as to electrically coupled to the substrate.

7. The method according to claim 6, wherein in etching the stack of the plurality of interlayer dielectric layers, an upper interlayer dielectric layer among the plurality of the interlayer dielectric layers has an etching rate lower than a lower interlayer dielectric layer among the plurality of the interlayer dielectric layers.

8. The method according to claim 1, further comprising forming a diffusion barrier pattern between the metal interconnect pattern and the second insulation pattern.

9. The method according to claim 8, wherein the diffusion barrier layer comprises nitride.

10. The method according to claim 1, wherein the height of the plug is 5% to 15% of the height of the metal interconnect pattern.

11. The method according to claim 1, further comprising:
depositing a barrier metal on a resulting structure including the first hole between the forming of the first hole and the forming of the plug; and
etching the barrier metal to expose the metal interconnect pattern.

12. A semiconductor device comprising:
a semiconductor substrate including a first contact plug;
a metal interconnection pattern having a lower end electrically coupled to the first contact plug;
a plug having a lower end electrically coupled to an upper end of the metal interconnect pattern; and
a second contact plug having a lower end electrically coupled to an upper end of the plug.

13. The semiconductor device according to claim 12, wherein an upper width of the first contact plug is narrower than a lower width of the first contact plug.

14. The semiconductor device according to claim 12, wherein the metal interconnect pattern comprises a barrier metal and copper (Cu).

15. The semiconductor device according to claim 12, wherein each of the first and second contact plugs comprises a barrier metal and tungsten (W).

16. The semiconductor device according to claim 12, wherein the height of the plug is 5% to 15% of the height of the metal interconnect pattern.

17. A semiconductor device comprising:
a semiconductor substrate;
a first contact plug formed over the semiconductor substrate, an upper portion of the first contact plug configured narrower than a lower portion of the first contact pad;
a metal interconnect pattern formed over the first contact plug and configured to be electrically coupled to the first contact plug; and
a second contact plug formed over the metal interconnection pattern and configured to be electrically coupled to the interconnect pattern.

18. The semiconductor device according to claim 17, further comprising a plug configured to be electrically coupled to the metal interconnect pattern and the second contact plug.
